(19) United States
(12) Patent Application Publication
(10) Pub. No.: US 2025/0062168 A1
(43) Pub. Date: Feb. 20, 2025

(54) Method and Stiffeners for Package Level Warpage Modulation

(71) Applicant: Intel Corporation, Santa Clara, CA (US)

(72) Inventors: Justin WHETTEN, Gilbert, AZ (US); Zhou YANG, Chandler, AZ (US); Zheng KANG, Chandler, AZ (US); Haowen LIU, Chandler, AZ (US); Bassam ZIADEH, Gilbert, AZ (US); Vijay Krishnan SUBRAMANIAN, Gilbert, AZ (US); John HARPER, Chandler, AZ (US); Pramod MALATKAR, Chandler, AZ (US); Patrick NARDI, Scottsdale, AZ (US); Anthony MONTERROSA, Chandler, AZ (US); Michael TAN, Gilbert, AZ (US); Sean BUSHELL, Peoria, AZ (US)

(21) Appl. No.: 18/451,852

(22) Filed: Aug. 18, 2023

(51) Int. Cl. H01L 23/24; B23K 26/362; H01L 21/268; H01L 21/67

(52) U.S. Cl. CPC H01L 23/24; B23K 26/362; H01L 21/268; H01L 21/67288; B23K 2101/40; H01L 23/49816; H01L 24/16; H01L 24/32; H01L 24/73; H01L 2224/16225; H01L 2224/32225; H01L 2224/73204; H01L 2924/1711; H01L 2924/37001

(57) ABSTRACT

The present disclosure is directed to a patterned stiffener that includes a metallic body, which is a component of and is attached to a semiconductor device platform for providing rigidity. In an aspect, there are patterned sections formed on the metallic body that act to modulate the metallic body to obtain a desired configuration for the semiconductor device platform. In another aspect, the present disclosure is also directed to a method that includes providing a platform for forming an electronic component, disposing a stiffener having a metallic body on the platform, disposing at least one semiconductor device onto the platform, performing one or more bonding process steps, and exposing the stiffener to localized heating to modulate changes in the stiffener to a pre-determined shape or desired configuration.

### BACKGROUND

For integrated circuit design and manufacturing, the need to improve performance and lower costs are constant challenges. The high-volume manufacturing (HVM) of semiconductor packages may produce yield losses caused by package warpage during the assembly process. Package warpage may be the result of multiple factors such as coefficient of thermal expansion (CTE) mismatches, the stack-up of different types of components, and the various thermal processing steps that the semiconductor packages undergo during the assembly process. An “imbalance” in a semiconductor package's thermal profile may result in a package warpage that is beyond the acceptable thresholds.

Presently, warpage mitigation solutions are often global solutions that deploy a variety of technologies and approaches to “balancing” the CTEs of the different components, e.g., copper traces/routing, copper core balls, etc., to address the mismatches within the semiconductor package. Other solutions include deploying different materials in the assembly process to stiffen the semiconductor package, e.g., epoxy formulations, mold, etc.

One approach to controlling warpage is to use a mechanical part, such as a stiffener, to improve the strength of package substrates and/or printed circuit boards (PCB) and minimize the warpage. The stiffener enhances the durability of the package substrate and PCB by adding thickness and reinforcing, for example, the areas in which components will be mounted. For package substrates, however, the addition of a stiffener may have an impact on the cost and manufacturing time for producing the semiconductor package and may not entirely counteract the sources of the package warpage problem. The ability to “modulate” package warpage to achieve more uniform warpage profiles and shapes may provide a solution to improving the yields of semiconductor packages during assembly processes.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows an exemplary representation of an electronic component according to an aspect of the present disclosure;

FIGS. 2A, 2B, and 2C show an exemplary representation of warpage profiles according to an aspect of the present disclosure;

FIG. 3 shows an exemplary representation of an electronic component according to an aspect of the present disclosure;

FIGS. 4A, 4B, 4C, and 4D show exemplary representations of patterns that may be applied to modulate a stiffener according to an aspect of the present disclosure; and

FIG. 5 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

The present disclosure provides an HVM-friendly approach to “modulate” the package warpage of stiffener-based products by exposing parts of the stiffener to patterned, localized heating. In an aspect, the heating may be performed by laser ablation that may induce localized stresses and alter the grain boundaries of the stiffener, which results in the modulating of the shape of the stiffener together with the package substrate. The warpage is a critical parameter to control as it can impact yield at various operations and steps within the package assembly/test/mount process.

The present disclosure is directed to a patterned stiffener that includes a metallic body, which is a component of and is attached to a semiconductor device platform for providing rigidity. In an aspect, there are patterned sections formed in the metallic body that act to modulate the metallic body to obtain a desired configuration for the semiconductor device platform.

The present disclosure is also directed to a method that includes providing a platform for forming an electronic component, disposing a stiffener having a metallic body on the platform, disposing at least one semiconductor device onto the platform, performing one or more bonding process steps, and exposing the stiffener to localized heating to modulate changes in the stiffener to a pre-determined shape or desired configuration, which may be nearly identical to a pre-processing configuration.

The present disclosure is further directed to a semiconductor package including a package substrate, a metallic body positioned on the package substrate to provide rigidity with the metallic body having one or more patterned sections formed thereon to enable the metallic body to obtain a desired warpage configuration on the package substrate and a semiconductor device.

The technical advantages of the present disclosure include, but are not limited to:
(i) providing a stiffener that may be modulated or adjusted to overcome package level warpage of stiffener-based products;
(ii) providing stiffener-based products with more uniform warpage profiles to improve product yields when using surfacing mounting technology;
(iii) providing a method that provides for localized heating of the stiffener using pre-determined patterns that may be used with high-volume manufacturing on a unit-by-unit basis and at any stage of the assembly process to improve product yields; and
(iv) providing a method that uses readily available lasers and other equipment to perform the localized heating of the stiffener.

To more readily understand and put into practical effect the present structures and methods for warpage modulation, which may be used for improving product yields, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

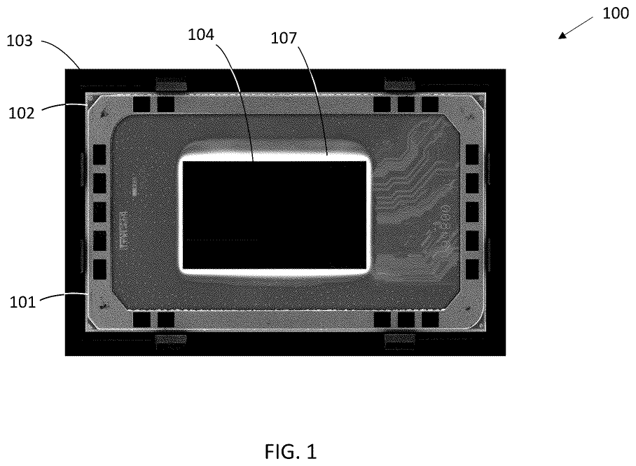

FIG. 1 shows an exemplary representation of a top view of an electronic component 100 according to an aspect of the present disclosure. The electronic component 100 may have a stiffener 101 having a metallic body, which may be positioned on a package substrate 102. A semiconductor die 104 may be surface mounted onto the package substrate 102 and further secured by an underfilling 107. The package substrate 102 may be further positioned on a printed circuit board (PCB) 103.

In an aspect, the present stiffeners 101 are applied as a frame or ring around the outer perimeter of the package substrate 102 and may have a pre-processing configuration that is essentially flat (i.e., with no curvature) and approximately co-planar with an upper surface of the package substrate 102. The stiffener 101 may be made of stainless steel or other similar alloy material. It is well-known that metal-based stiffeners provide good stiffening properties, however, their CTE may be different and may sometimes even have competing properties at low and high temperatures as compared with other materials used in a electronic component.

The present stiffener 101 may be “modulated”, which means applying heat in a designated pattern to change the curvature of a stiffener. The stiffener 101 may have been altered due to warpage resulting from typical thermal processing steps and the modulation enables an electronic component to maintain warpage error tolerances determined at the design stage.

In another aspect, it should be understood that it is within the scope of the present disclosure to position a present stiffener on any semiconductor platform, such as a PCB, to provide rigidity to an electronic component and to modulate the stiffener positioned on the semiconductor platform to obtain a desired configuration having a required planarity.

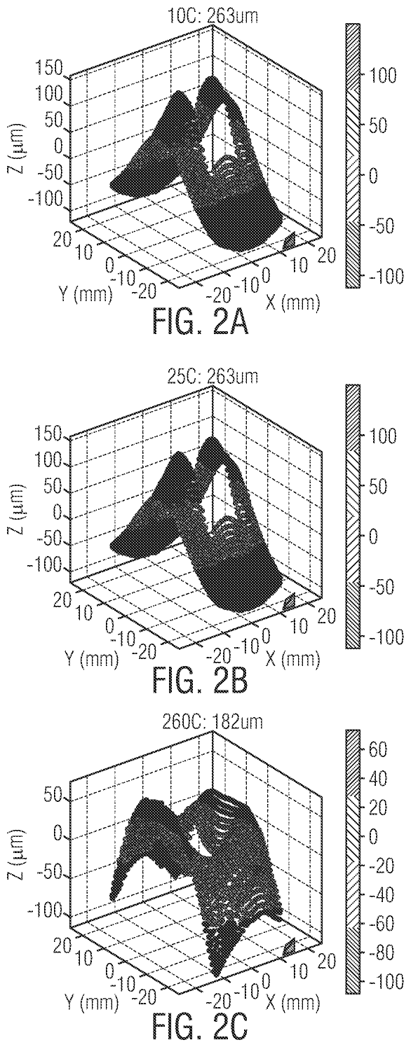

FIGS. 2A, 2B, and 2C show an exemplary representation of warpage profiles according to an aspect of the present disclosure. The warpage profiles of a semiconductor package may be measured with a machine vision metrology tool; for example, an Intekplus IPIS500, which is a white light triangulation metrology tool. Each figure shows an end-of-line package substrate with a ring stiffener and die, and the package substrate has a convex warpage profile with the corners down and the center up. The warpage profiles in FIGS. 2A, 2B, and 2C are not ideal for package mounting because they may lead to non-wet openings and other defects in the ball grid array (BGA) attachment with a printed circuit board. In such cases, the stiffeners on the semiconductor package may be permanently modulated by discrete laser patterning on the stiffeners to remediate the tube-like warpage as described below.

In another aspect, using the warpage profile analysis, the present method may provide a design team the ability to model both large and minute changes to a stiffener and determine the exact changes needed to fine-tune package shape from a semiconductor package having an extreme warpage (i.e., unusable or marginally useable semiconductor package) to a semiconductor package having a desired configuration or ideal warpage (i.e., little or no curvature), which may be nearly identical to a pre-processing configuration. The warpage profile analysis may also be performed after one or more convenient steps, e.g., a high-temperature processing step, in high-volume manufacturing production. Similarly, the warpage modulation process may be performed before or after a warpage profile analysis.

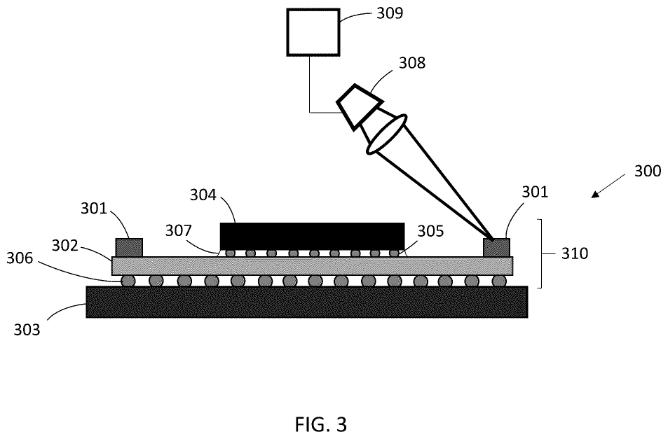

FIG. 3 shows an exemplary representation of a side view of an electronic component 300 according to an aspect of the present disclosure. The electronic component 300 may have a stiffener 301 having a metallic body, which may be positioned on a package substrate 302. A semiconductor die 304 may be positioned on and attached by a plurality of solder balls 305 to the package substrate 302 and secured by an underfilling 307, which together form a semiconductor package 310. The package substrate 302 may be further positioned on and attached by a plurality of solder balls 306 to a printed circuit board (PCB) 303.

In an aspect, the stiffener 301 may be exposed to laser energy from a laser tool 308 that may be connected to a controller 309. The laser tool 308 may create local hot spots that cause morphology changes in the stiffener 301, including on the surface of the stiffener 308. The high transient temperature and large temperature gradient caused by the laser tool 308 induce thermal stresses, phase changes, and possible grain boundary changes (i.e., modulated microstructures), which induce residual plastic stresses that can modulate the shape of stiffener at the high and low sections and, therefore, the semiconductor package 310. The magnitude and location can be controlled via the use of laser ablation and pattern settings provided by the controller 309, such as power settings, raster scan speed, pattern designs, etc. For example, the laser tool 308 may have, among other components, a mirror galvanometer (not shown) that may allow control of user-defined laser locations (i.e., patterns) and intensities.

The present disclosure enables warpage modulation on a “demand” basis, i.e., at any stage of an assembly process, and on a unit-by-unit basis as needed. This flexibility may greatly simplify the thermomechanical design for controlling warpage. As such, the present method may be used at any point in the manufacturing/assembly process to correct underlying warpage issues, including at the end of line. Additionally, the present method may provide modulation using laser heating/energy at specific regions; for example, one corner that is bending too far down can be locally bent up by laser heating using this no-contact method. Finally, the present method may provide semiconductor packages with uniform shapes, which will improve product yields from an assembly process.

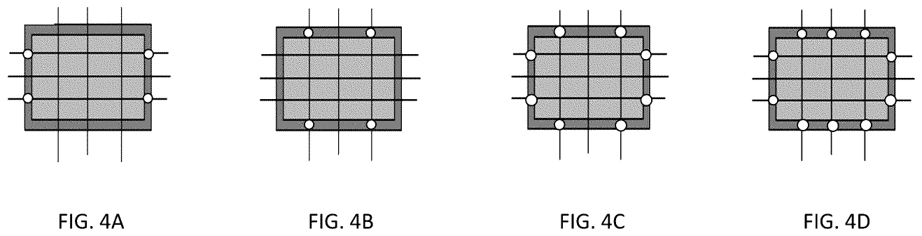

FIGS. 4A. 4B, 4C, and 4D show exemplary representations of laser patterns that may be applied to modulate a stiffener according to an aspect of the present disclosure. These figures illustrate examples of patterns and shapes that could be patterned onto a steel stiffener.

In an aspect, the present method includes performing warpage curvature analysis during the design stage, prototype development stage, and production stage. For example, the present patterns may be determined with modeling at the design stage. Additionally, a mechanical model of the package may be built and compared with a nominal production package shape and/or an ideal package shape. Using these analyses, the locations and intensity of laser processing needed on the stiffener may be determined to adjust the end package warpage.

In an aspect, the patterns may be placed geometrically or at known high and low sections based on warpage analysis on test or production samples to achieve an optimal shape or pre-determined configuration. The list of shapes used in the patterns may include circles, lines, or polygons and they can be repeated patterns or pseudo-random, based on the analysis. The laser parameters are tuned in such a manner that tensile or compressive stresses can be built up in the steel or stiffener material in modulating their microstructures.

Upon further analysis using TOF-SIMS or SEM techniques, it is possible to observe thermal impacts from the present laser heating/ablation technique as it will result in local grain boundary, hardness, and modulus changes. Additionally, it may be possible visually detect the location of the laser ablation process from a smoother and/or discolored surface on the steel.

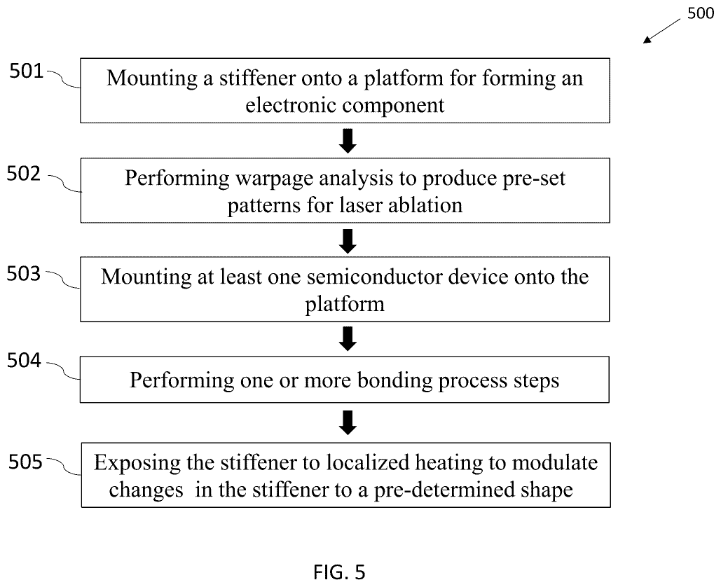

FIG. 5 shows a simplified flow diagram for an exemplary method according to an aspect of the present disclosure.

The operation 501 may be directed to mounting a stiffener onto a platform for forming an electronic component.

The operation 502 may be directed to performing warpage analysis to produce pre-set patterns for laser ablation. The warpage analysis may be conducted at any point after a stiffener or semiconductor device is attached to a semiconductor platform directed to high and low sections.

The operation 503 may be directed to mounting at least one semiconductor device onto the platform.

The operation 504 may be directed to performing one or more bonding process steps.

The operation 505 may be directed to exposing the stiffener to localized heating to modulate changes in the stiffener to a pre-determined shape. The pre-set pattern will be used to produce a patterned stiffener. The patterned stiffener may have a pre-determined shape/configuration that meets the warpage thresholds for an electronic component.

It will be understood that any property described herein for a particular stiffener structure and method for modulating a stiffener may also hold for any electronic component using the patterned stiffener described herein. It will also be understood that any property described herein for a specific method may hold for any of the methods described herein. Furthermore, it will be understood that for any semiconductor package using the present stiffeners and the methods described herein, not necessarily all the components or operations described will be shown in the accompanying drawings or method, but only some (not all) components or operations may be disclosed.

To more readily understand and put into practical effect the present stiffener and methods for laser ablation of the stiffener, they will now be described by way of examples. For the sake of brevity, duplicate descriptions of features and properties may be omitted.

### Examples

Example 1 provides a patterned stiffener including a metallic body, for which the metal body is a component of a semiconductor device platform for providing rigidity, and the metallic body includes one or more patterned sections, for which the one or more patterned sections are formed in the metallic body to enable the metallic body to obtain a desired configuration for the semiconductor device platform.

Example 2 may include the patterned stiffener of example 1 and/or any other example disclosed herein, for which the metallic body includes a frame that is positioned along a periphery of an upper surface of the semiconductor device platform.

Example 3 may include the patterned stiffener of example 1 and/or any other example disclosed herein, for which the one or patterned sections comprise microstructure changes in grain boundaries and/or phase changes in the metallic body.

Example 4 may include the patterned stiffener of example 2 and/or any other example disclosed herein, for which the frame of the metallic body is provided with a pre-processing configuration that is approximately co-planar with the upper surface of the semiconductor device platform.

Example 5 may include the patterned stiffener of example 4 and/or any other example disclosed herein, for which the desired configuration is nearly identical to the pre-processing configuration.

Example 6 may include the patterned stiffener of example 1 and/or any other example disclosed herein, for which the semiconductor device platform is a package substrate.

Example 7 may include the patterned stiffener of example 1 and/or any other example disclosed herein, for which the semiconductor device platform is a printed circuit board.

Example 8 may include the patterned stiffener of example 1 and/or any other example disclosed herein, for which the one or more patterned sections are formed by laser ablation.

Example 9 may include the patterned stiffener of example 8 and/or any other example disclosed herein, for which the one or more patterned sections comprise repeating or pseudo-random patterns of circles, lines, or polygons formed by the laser ablation.

Example 10 provides a method providing a platform for forming an electronic component, disposing a stiffener on the platform, for which the stiffener includes a metallic body, disposing at least one semiconductor device onto the platform, performing one or more bonding process steps, and exposing the stiffener to localized heating to modulate changes in the stiffener to a pre-determined shape.

Example 11 may include the method of example 10 and/or any other example disclosed herein, for which the localized heating is provided by a laser.

Example 12 may include the method of example 10 and/or any other example disclosed herein, further including a warpage analysis to determine curvatures of the stiffener at different intervals of forming the electronic component.

Example 13 may include the method of example 12 and/or any other example disclosed herein, for which the curvatures comprise high and low sections of the stiffener formed by the one or more bonding process steps.

Example 14 may include the method of example 10 and/or any other example disclosed herein, for which the modulated changes in the stiffener comprises controlling tensile and compressive strains in the stiffener.

Example 15 may include the method of example 11 and/or any other example disclosed herein, for which the laser produces one or more patterned sections including repeating or pseudo-random patterns of circles, lines, or polygons on the stiffener.

Example 16 may include the method of example 11 and/or any other example disclosed herein, further including a control unit for directing the laser and providing the laser with the pre-determined shape.

Example 17 provides a semiconductor package including a package substrate, and a metallic body, for which the metal body is positioned on the package substrate to provide rigidity, the metallic body includes one or more patterned sections, for which the one or more patterned sections are formed in the metallic body to enable the metallic body to obtain a desired configuration for the package substrate and a semiconductor device.

Example 18 may include the semiconductor package of example 17 and/or any other example disclosed herein, for which the metallic body is a stiffener forming a frame around the semiconductor device.

Example 19 may include the semiconductor package of example 17 and/or any other example disclosed herein, for which the one or more patterned sections comprise repeating or pseudo-random patterns of circles, lines, or polygons.

Example 20 may include the semiconductor package of example 17 and/or any other example disclosed herein, for which the one or patterned sections provide modulated microstructures including changes in grain boundaries and/or phase changes in the metallic body.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A patterned stiffener comprising:
a metallic body, wherein the metal body is a component of a semiconductor device platform for providing rigidity; and
the metallic body comprised one or more patterned sections, wherein the one or more patterned sections are formed in the metallic body to enable the metallic body to obtain a desired configuration for the semiconductor device platform.

2. The patterned stiffener of claim 1, wherein the metallic body comprises a frame that is positioned along a periphery of an upper surface of the semiconductor device platform.

3. The patterned stiffener of claim 1, wherein the one or patterned sections comprise microstructure changes in grain boundaries and/or phase changes in the metallic body.

4. The patterned stiffener of claim 2, wherein the frame of the metallic body is provided with a pre-processing configuration that is approximately co-planar with the upper surface of the semiconductor device platform.

5. The patterned stiffener of claim 4, wherein the desired configuration is nearly identical to the pre-processing configuration.

6. The patterned stiffener of claim 1, wherein the semiconductor device platform is a package substrate.

7. The patterned stiffener of claim 1, wherein the semiconductor device platform is a printed circuit board.

8. The patterned stiffener of claim 1, wherein the one or more patterned sections are formed by laser ablation.

9. The patterned stiffener of claim 8, wherein the one or more patterned sections comprise repeating or pseudo-random patterns of circles, lines, or polygons formed by the laser ablation.

10. A method comprising:
providing a platform for forming an electronic component;
disposing a stiffener on the platform, wherein the stiffener comprises a metallic body;
disposing at least one semiconductor device onto the platform;
performing one or more bonding process steps; and
exposing the stiffener to localized heating to modulate changes in the stiffener to a pre-determined shape.

11. The method of claim 10, wherein the localized heating is provided by a laser.

12. The method of claim 10, further comprising a warpage analysis to determine curvatures of the stiffener at different intervals of forming the electronic component.

13. The method of claim 12, wherein the curvatures comprise high and low sections of the stiffener formed by the one or more bonding process steps.

14. The method of claim 10, wherein the modulated changes in the stiffener comprises controlling tensile and compressive strains in the stiffener.

15. The method of claim 11, wherein the laser produces one or more patterned sections comprising repeating or pseudo-random patterns of circles, lines, or polygons on the stiffener.

16. The method of claim 11, further comprising a control unit for directing the laser and providing the laser with the pre-determined shape.

17. A semiconductor package comprising:
a package substrate;
a metallic body, wherein the metal body is positioned on the package substrate to provide rigidity;
the metallic body comprises one or more patterned sections, wherein the one or more patterned sections are formed in the metallic body to enable the metallic body to obtain a desired configuration for the package substrate; and
a semiconductor device.

18. The semiconductor package of claim 17, wherein the metallic body is a stiffener forming a frame around the semiconductor device.

19. The semiconductor package of claim 17, wherein the one or more patterned sections comprise repeating or pseudo-random patterns of circles, lines, or polygons.

20. The semiconductor package of claim 17, wherein the one or patterned sections provide modulated microstructures comprising changes in grain boundaries and/or phase changes in the metallic body.
